(19) United States
(12) Patent Application Publication
(10) Pub. No.: US 2019/0027419 A1
(43) Pub. Date: Jan. 24, 2019

(54) FAN-OUT SEMICONDUCTOR PACKAGE AND PACKAGE SUBSTRATE COMPRISING THE SAME

(71) Applicant: SAMSUNG ELECTRO-MECHANICS CO., LTD., Suwon-si (KR)

(72) Inventors: Chang Bo LEE, Suwon-si (KR); Joon Seok OH, Suwon-si (KR); Hyun Chul JUNG, Suwon-si (KR); Jeong Ho YEO, Suwon-si (KR)

(21) Appl. No.: 15/829,045

(22) Filed: Dec. 1, 2017

(30) Foreign Application Priority Data
Jul. 18, 2017 (KR) 10-2017-0090763

(51) Int. Cl. H01L 23/367; H01L 23/552; H01L 23/31; H01L 23/24; H01L 23/373; H01L 23/00

(52) U.S. Cl. CPC H01L 23/3675; H01L 23/552; H01L 23/3135; H01L 23/24; H01L 23/3733; H01L 2224/02381; H01L 24/02; H01L 2224/02331; H01L 2224/02371; H01L 2224/02379; H01L 23/3737

(57) ABSTRACT

A fan-out semiconductor package includes: a semiconductor chip having an active surface having connection pads disposed thereon and an inactive surface opposing the active surface; an encapsulant encapsulating at least portions of the inactive surface of the semiconductor chip; a connection member disposed on the active surface of the semiconductor chip and including a redistribution layer electrically connected to the connection pads of the semiconductor chip; a reinforcing plate disposed on the encapsulant and having a first surface facing the inactive surface of the semiconductor chip and a second surface opposing the first surface; and rigid patterns formed on at least one of the first surface and the second surface of the reinforcing plate.

### CROSS-REFERENCE TO RELATED APPLICATION(S)

This application claims the benefit of priority to Korean Patent Application No. 10-2017-0090763, filed on Jul. 18, 2017 in the Korean Intellectual Property Office, the disclosure of which is incorporated herein by reference in its entirety.

### BACKGROUND

### 1. Field

The present disclosure relates to a semiconductor package, and more particularly, to a fan-out semiconductor package in which connection terminals may extend outwardly of a region in which a semiconductor chip is disposed.

### 2. Description of Related Art

A significant recent trend in the development of technology related to semiconductor chips has been to reduce the size of semiconductor chips. Therefore, in the field of package technology, in accordance with a rapid increase in demand for small-sized semiconductor chips, or the like, the implementation of a semiconductor package having a compact size while including a plurality of pins has been demanded.

One type of package technology suggested to satisfy the technical demand as described above is a fan-out package. Such a fan-out package has a compact size and may allow a plurality of pins to be implemented by redistributing connection terminals outwardly of a region in which a semiconductor chip is disposed.

### SUMMARY

An aspect of the present disclosure may provide a fan-out semiconductor package in which a warpage problem may be effectively solved, and a package substrate including the same.

According to an aspect of the present disclosure, a fan-out semiconductor package may be provided, in which a reinforcing plate having rigid patterns formed on at least one surface thereof is attached to an encapsulant encapsulating a semiconductor chip.

According to an aspect of the present disclosure, a fan-out semiconductor package may include: a semiconductor chip having an active surface having connection pads disposed thereon and an inactive surface opposing the active surface; an encapsulant encapsulating at least portions of the inactive surface of the semiconductor chip; a connection member disposed on the active surface of the semiconductor chip and including a redistribution layer electrically connected to the connection pads of the semiconductor chip; a reinforcing plate disposed on the encapsulant and having a first surface facing the inactive surface of the semiconductor chip and a second surface opposing the first surface; and rigid patterns formed on the first surface and/or the second surface of the reinforcing plate.

According to another aspect of the present disclosure, a package substrate may include: a plurality of unit packages each including a semiconductor chip having an active surface having connection pads disposed thereon and an inactive surface opposing the active surface, an encapsulant encapsulating at least portions of the inactive surface of the semiconductor chip, a connection member disposed on the active surface of the semiconductor chip and including a redistribution layer electrically connected to the connection pads of the semiconductor chip, a reinforcing plate disposed on the encapsulant and having a first surface facing the inactive surface of the semiconductor chip and a second surface opposing the first surface, and rigid patterns formed on at least one of the first surface and the second surface of the reinforcing plate, wherein a larger number of rigid patterns are formed in unit packages, among the plurality of unit packages, in which unit warpage is relatively high, than in unit packages, among the plurality of unit packages, in which unit warpage is relatively low.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is schematic cross-sectional views illustrating a packaging process of a fan-in semiconductor package;

FIG. 5 is a schematic cross-sectional view illustrating a case in which a fan-in semiconductor package is mounted on an interposer substrate and is finally mounted on a main board of an electronic device;

FIG. 6 is a schematic cross-sectional view illustrating a case in which a fan-in semiconductor package is embedded in an interposer substrate and is finally mounted on a main board of an electronic device;

FIG. 7 is a schematic cross-sectional view illustrating a fan-out semiconductor package;

FIG. 8 is a schematic cross-sectional view illustrating a case in which a fan-out semiconductor package is mounted on a main board of an electronic device;

FIG. 9 is a schematic cross-sectional view illustrating an example of a fan-out semiconductor package;

FIG. 10 is a schematic plan view taken along line I-I′ of the fan-out semiconductor package of FIG. 9;

FIG. 11 is a schematic cross-sectional view illustrating another example of a fan-out semiconductor package;

FIG. 12 is a schematic cross-sectional view illustrating another example of a fan-out semiconductor package;

FIG. 13 is a schematic cross-sectional view illustrating another example of a fan-out semiconductor package;

FIG. 14 is a schematic cross-sectional view illustrating another example of a fan-out semiconductor package;

FIG. 15 is a schematic cross-sectional view illustrating another example of a fan-out semiconductor package;

FIG. 16 is a schematic cross-sectional view illustrating another example of a fan-out semiconductor package;

FIG. 17 is a schematic cross-sectional view illustrating another example of a fan-out semiconductor package;

FIG. 18 is a schematic cross-sectional view illustrating another example of a fan-out semiconductor package; and

FIG. 19 is a schematic plan view illustrating an example of a package substrate including a plurality of fan-out semiconductor packages.

### DETAILED DESCRIPTION

Hereinafter, exemplary embodiments in the present disclosure will be described with reference to the accompanying drawings. In the accompanying drawings, shapes, sizes, and the like, of components may be exaggerated or shortened for clarity.

The term “an exemplary embodiment” used herein does not refer to the same exemplary embodiment, and is provided to emphasize a particular feature or characteristic different from that of another exemplary embodiment. However, exemplary embodiments provided herein are considered to be able to be implemented by being combined in whole or in part one with another. For example, one element described in a particular exemplary embodiment, even if it is not described in another exemplary embodiment, may be understood as a description related to another exemplary embodiment, unless an opposite or contradictory description is provided therein.

The meaning of a “connection” of a component to another component in the description includes an indirect connection through a third component as well as a direct connection between two components. In addition, “electrically connected” means the concept including a physical connection and a physical disconnection. It can be understood that when an element is referred to with “first” and “second”, the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

Herein, an upper portion, a lower portion, an upper side, a lower side, an upper surface, a lower surface, and the like, are decided in the attached drawings. For example, a first connection member is disposed on a level above a redistribution layer. However, the claims are not limited thereto. In addition, a vertical direction refers to the abovementioned upward and downward directions, and a horizontal direction refers to a direction perpendicular to the abovementioned upward and downward directions. In this case, a vertical cross section refers to a case taken along a plane in the vertical direction, and an example thereof may be a cross-sectional view illustrated in the drawings. In addition, a horizontal cross section refers to a case taken along a plane in the horizontal direction, and an example thereof may be a plan view illustrated in the drawings.

Terms used herein are used only in order to describe an exemplary embodiment rather than limiting the present disclosure. In this case, singular forms include plural forms unless interpreted otherwise in context.

Electronic Device

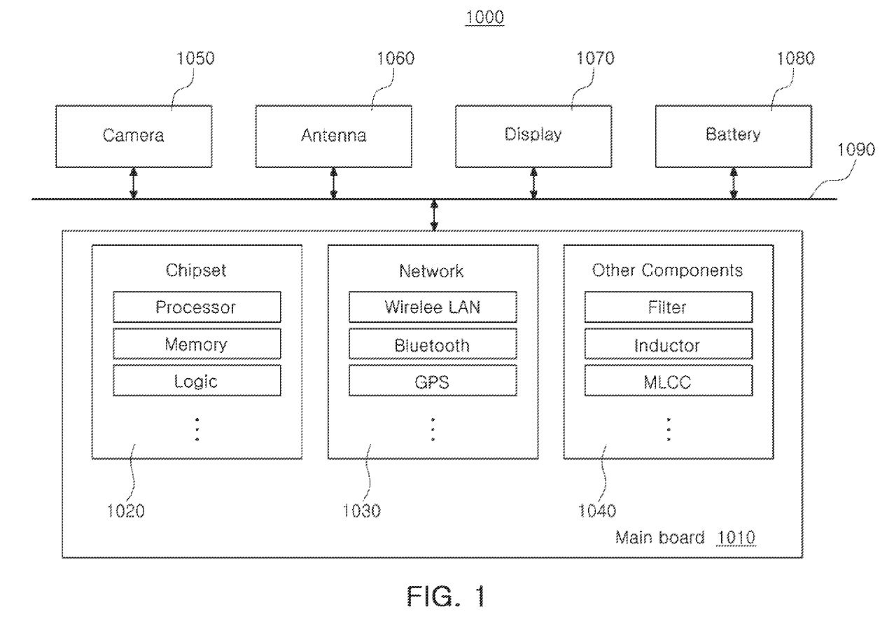

FIG. 1 is a schematic block diagram illustrating an example of an electronic device system.

Referring to FIG. 1, an electronic device 1000 may accommodate a main board 1010 therein. The main board 1010 may include chip-related components 1020, network-related components 1030, other components 1040, and the like, physically or electrically connected thereto. These components may be connected to others to be described below to form various signal lines 1090.

The chip-related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip-related components 1020 are not limited thereto, but may also include other types of chip related components. In addition, the chip-related components 1020 may be combined with each other.

The network-related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols designated after the abovementioned protocols. However, the network-related components 1030 are not limited thereto, but may also include a variety of other wireless or wired standards or protocols. In addition, the network-related components 1030 may be combined with each other, together with the chip-related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip-related components 1020 or the network-related components 1030 described above.

Depending on a type of the electronic device 1000, the electronic device 1000 may include other components that may or may not be physically or electrically connected to the main board 1010. These other components may include, for example, a camera module 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

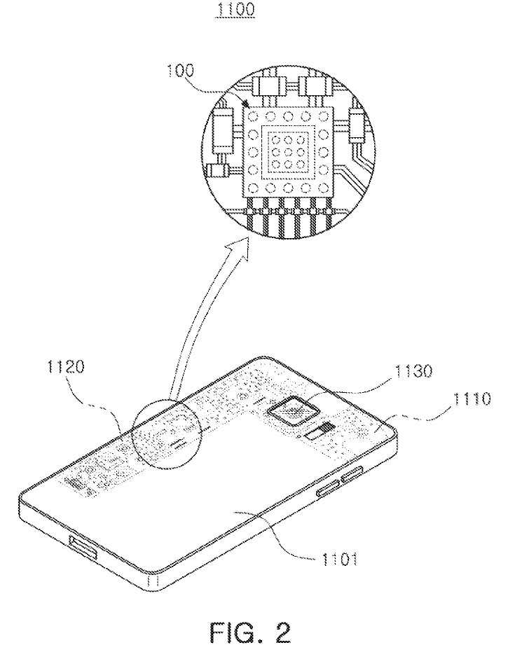

FIG. 2 is a schematic perspective view illustrating an example of an electronic device.

Referring to FIG. 2, a semiconductor package may be used for various purposes in the various electronic devices 1000 as described above. For example, a motherboard 1110 may be accommodated in a body 1101 of a smartphone 1100, and various electronic components 1120 may be physically or electrically connected to the motherboard 1110. In addition, other components that may or may not be physically or electrically connected to the motherboard 1110, such as a camera module 1130, may be accommodated in the body 1101. Some of the electronic components 1120 may be the chip related components, and the semiconductor package 100 may be, for example, an application processor among the chip related components, but is not limited thereto. The electronic device is not necessarily limited to the smartphone 1100, but may be other electronic devices as described above.

Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, but may be packaged and used in an electronic device, or the like, in a packaged state.

Here, semiconductor packaging is required due to the existence of a difference in a circuit width between the semiconductor chip and a main board of the electronic device in terms of electrical connections. In detail, a size of connection pads of the semiconductor chip and an interval between the connection pads of the semiconductor chip are very fine, but a size of component mounting pads of the main board used in the electronic device and an interval between the component mounting pads of the main board are significantly larger than those of the semiconductor chip. Therefore, it may be difficult to directly mount the semiconductor chip on the main board, and packaging technology for buffering a difference in a circuit width between the semiconductor chip and the main board is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

Fan-In Semiconductor Package

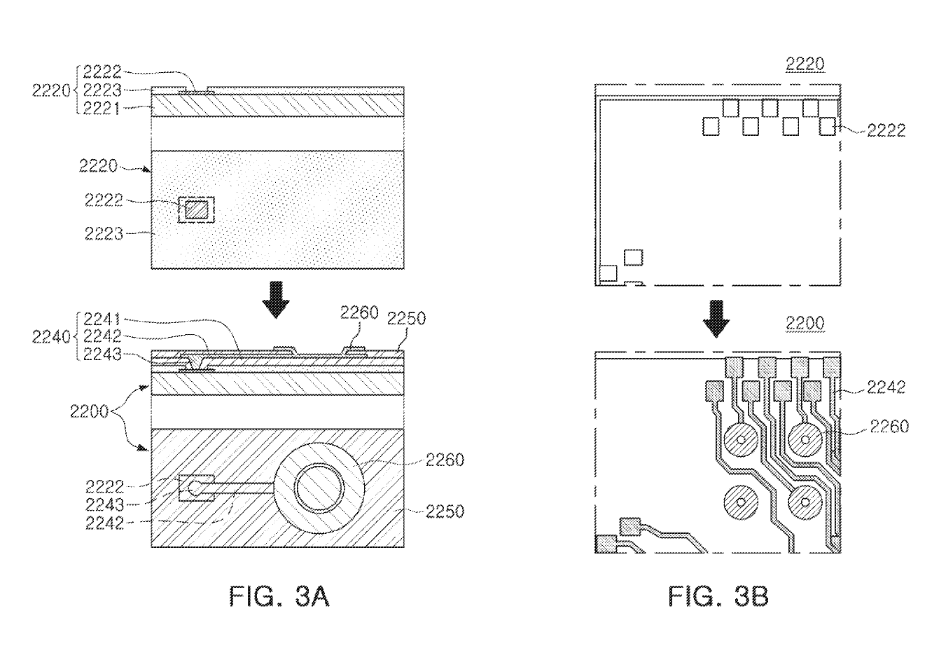

FIGS. 3A and 3B are schematic cross-sectional views illustrating states of a fan-in semiconductor package before and after being packaged.

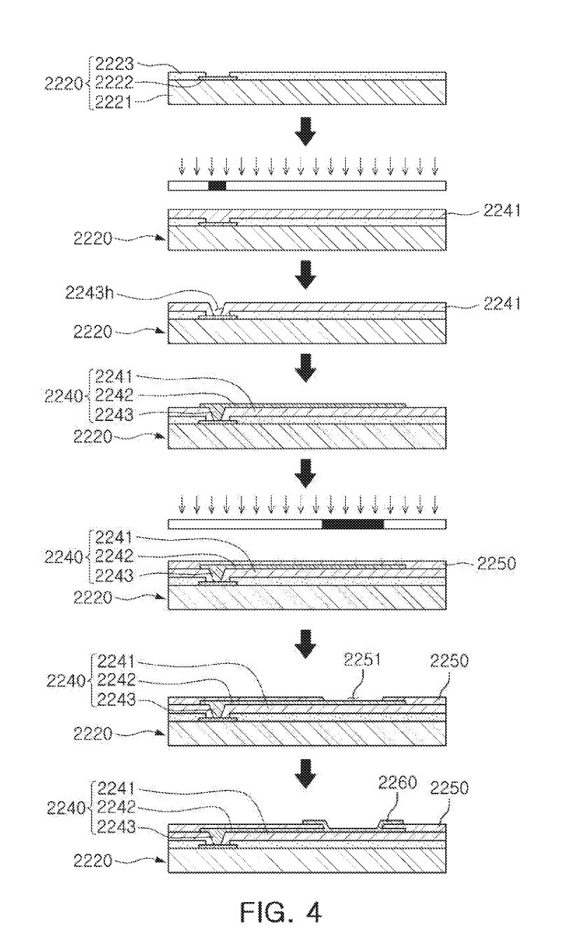

FIG. 4 is schematic cross-sectional views illustrating a packaging process of a fan-in semiconductor package.

Referring to the drawings, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide film, a nitride film, or the like, formed on one surface of the body 2221 and covering at least portions of the connection pads 2222. In this case, since the connection pads 2222 are significantly small, it is difficult to mount the integrated circuit (IC) on an intermediate level printed circuit board (PCB) as well as on the main board of the electronic device, or the like.

Therefore, a connection member 2240 may be formed depending on a size of the semiconductor chip 2220 on the semiconductor chip 2220 in order to redistribute the connection pads 2222. The connection member 2240 may be formed by forming an insulating layer 2241 on the semiconductor chip 2220 using an insulating material such as photoimagable dielectric (PID) resin, forming via holes 2243h opening the connection pads 2222, and then forming a redistribution layer 2242 and vias 2243. Then, a passivation layer 2250 protecting the connection member 2240 may be formed, an opening 2251 may be formed, and an underbump metal layer 2260, or the like, may be formed. That is, a fan-in semiconductor package 2200 including, for example, the semiconductor chip 2220, the connection member 2240, the passivation layer 2250, and the underbump metal layer 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has a large spatial limitation. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the main board of the electronic device. Here, even in a case that a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip may not be sufficient to directly mount the fan-in semiconductor package on the main board of the electronic device.

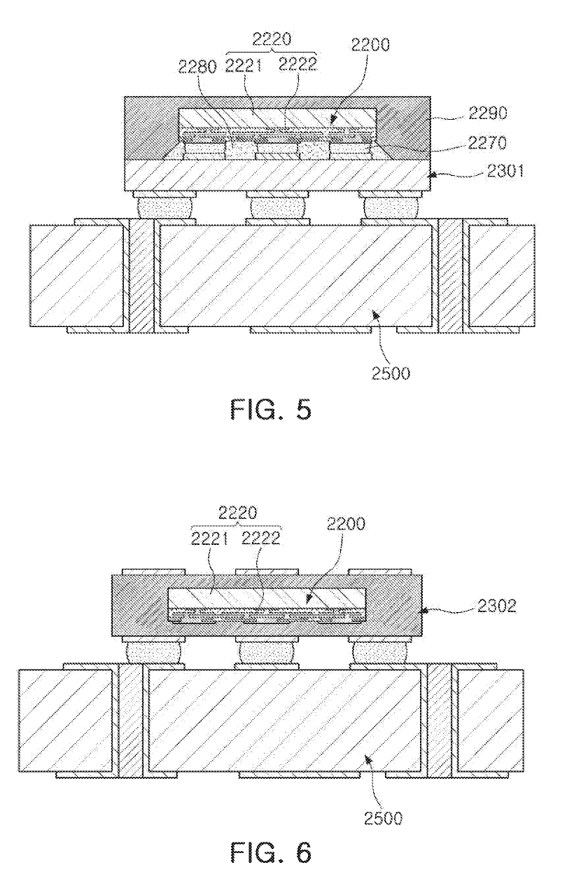

FIG. 5 is a schematic cross-sectional view illustrating a case in which a fan-in semiconductor package is mounted on an interposer substrate and is finally mounted on a main board of an electronic device.

FIG. 6 is a schematic cross-sectional view illustrating a case in which a fan-in semiconductor package is embedded in an interposer substrate and is finally mounted on a main board of an electronic device.

Referring to the drawings, in a fan-in semiconductor package 2200, connection pads 2222, that is, I/O terminals, of a semiconductor chip 2220 may be redistributed through an interposer substrate 2301, and the fan-in semiconductor package 2200 may be finally mounted on a main board 2500 of an electronic device in a state in which it is mounted on the interposer substrate 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate interposer substrate 2302, connection pads 2222, that is, I/O terminals, of the semiconductor chip 2220 may be redistributed by the interposer substrate 2302 in a state in which the fan-in semiconductor package 2200 is embedded in the interposer substrate 2302, and the fan-in semiconductor package 2200 may be finally mounted on a main board 2500 of an electronic device.

As described above, it may be difficult to directly mount and use the fan-in semiconductor package on the main board of the electronic device. Therefore, the fan-in semiconductor package may be mounted on the separate interposer substrate and be then mounted on the main board of the electronic device through a packaging process or may be mounted and used on the main board of the electronic device in a state in which it is embedded in the interposer substrate.

Fan-Out Semiconductor Package

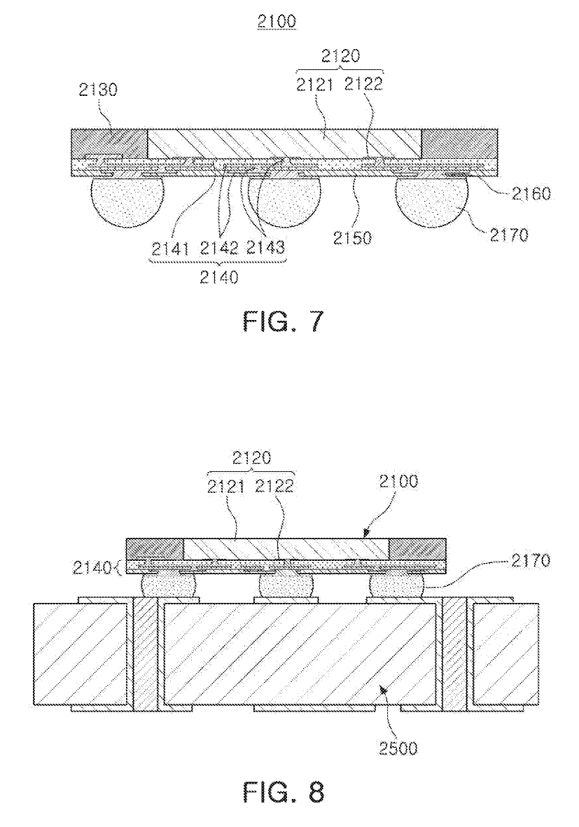

FIG. 7 is a schematic cross-sectional view illustrating a fan-out semiconductor package.

Referring to the drawing, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2150 may be further formed on the connection member 2140, and an underbump metal layer 2160 may be further formed in openings of the passivation layer 2150. Solder balls 2170 may be further formed on the underbump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the connection member formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection member formed on the semiconductor chip as described above. Therefore, even in a case that a size of the semiconductor chip is decreased, a standardized ball layout may be used in the fan-out semiconductor package as it is, such that the fan-out semiconductor package may be mounted on the main board of the electronic device without using a separate interposer substrate, as described below.

FIG. 8 is a schematic cross-sectional view illustrating a case in which a fan-out semiconductor package is mounted on a main board of an electronic device.

Referring to the drawing, a fan-out semiconductor package 2100 may be mounted on a main board 2500 of an electronic device through solder balls 2170, or the like. That is, as described above, the fan-out semiconductor package 2100 includes the connection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the main board 2500 of the electronic device without using a separate interposer substrate, or the like.

As described above, since the fan-out semiconductor package may be mounted on the main board of the electronic device without using the separate interposer substrate, the fan-out semiconductor package may be implemented at a thickness lower than that of the fan-in semiconductor package using the interposer substrate. Therefore, the fan-out semiconductor package may be miniaturized and thinned. In addition, the fan-out semiconductor package has excellent thermal characteristics and electrical characteristics, such that it is particularly appropriate for a mobile product. Therefore, the fan-out semiconductor package may be implemented in a form more compact than that of a general package-on-package (POP) type using a printed circuit board (PCB), and may solve a problem due to occurrence of a warpage phenomenon.

Meanwhile, the fan-out semiconductor package refers to package technology for mounting the semiconductor chip on the main board of the electronic device, or the like, as described above, and protecting the semiconductor chip from external impacts, and is a concept different from that of a printed circuit board (PCB) such as an interposer substrate, or the like, having a scale, a purpose, and the like, different from those of the fan-out semiconductor package, and having the fan-in semiconductor package embedded therein.

A fan-out semiconductor package in which a warpage problem may be effectively solved will hereinafter be described with reference to the drawings.

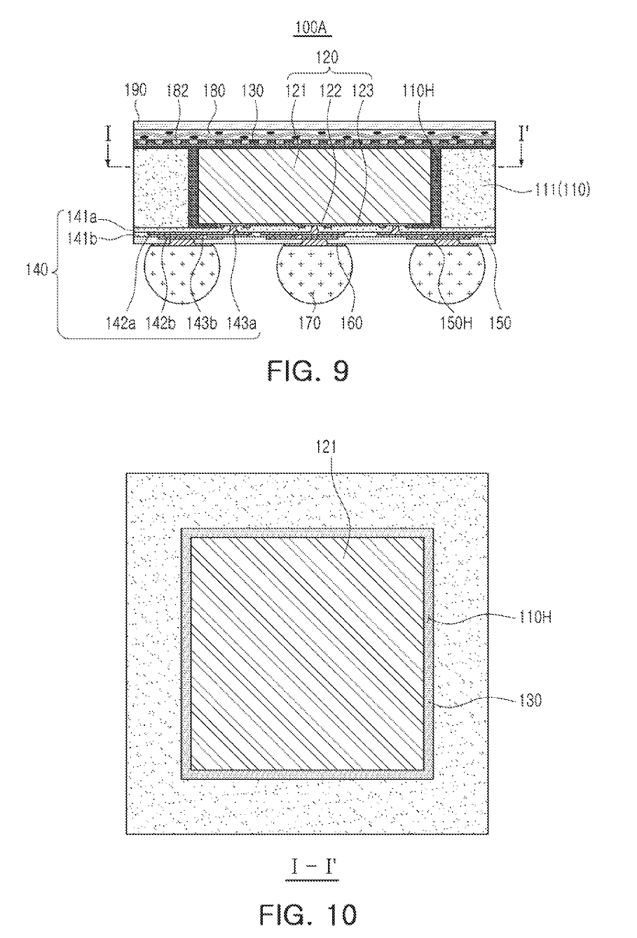

FIG. 9 is a schematic cross-sectional view illustrating an example of a fan-out semiconductor package.

FIG. 10 is a schematic plan view taken along line I-I′ of the fan-out semiconductor package of FIG. 9.

Referring to the drawings, a fan-out semiconductor package 100A according to an exemplary embodiment in the present disclosure may include a support member 110 having a through-hole 110H, a semiconductor chip 120 disposed in the through-hole 110H of the support member 110 and having an active surface having connection pads 122 disposed thereon and an inactive surface opposing the active surface, an encapsulant 130 encapsulating at least portions of the support member 110 and the inactive surface of the semiconductor chip 120, a connection member 140 disposed on the support member 110 and the active surface of the semiconductor chip 120, a passivation layer 150 disposed on the connection member 140, an underbump metal layer 160 disposed in openings 150H of the passivation layer 150, connection terminals 170 formed on the underbump metal layer 160, a reinforcing plate 180 disposed on the encapsulant 130, rigid patterns 182 formed on a lower surface of the reinforcing plate 180, and a resin layer 190 formed on the reinforcing plate 180.

For the purpose of mass production of a semiconductor package, a plurality of packages are manufactured using a wafer, a panel, or the like, and individual packages are obtained using a cutting process, or the like. However, when the plurality of packages are manufactured, a difference between unit warpages is generated within the panel for manufacturing the package due to a difference in a physical property such as a coefficient of thermal expansion (CTE), or the like, between various materials in the package or hardening contraction of a layer including a resin component such as an encapsulant, resulting in a difficulty in manufacturing products having the same quality due to a warpage problem. However, the fan-out semiconductor package 100A according to the exemplary embodiment may have a form in which the reinforcing plate 180 on which the rigid patterns 182 are formed is attached onto the encapsulant 130 to embed the rigid patterns 182 in the encapsulant 130. When the reinforcing plate 180 on which the rigid patterns 182 are formed is introduced, stress due to CTE characteristics and hardening contraction of the encapsulant 130 or the resin layer 190 may be controlled. Resultantly, unit warpages may be effectively controlled, such that the fan-out semiconductor packages 100A having substantially the same quality may be manufactured even in a case of being mass-produced. In addition, since the rigid patterns 182 control a flow of the encapsulant 130, non-uniformity of a thickness of the encapsulant 130 may be reduced, and a void defect or a bleeding defect of the encapsulant 130 may be prevented.

The respective components included in the fan-out semiconductor package 100A according to the exemplary embodiment will hereinafter be described in more detail.

The support member 110 may improve rigidity of the fan-out semiconductor package 100A depending on certain materials, and serve to secure uniformity of a thickness of the encapsulant 130. When through-wirings, or the like, are formed in the support member 110, the fan-out semiconductor package 100A may be utilized as a package-on-package (POP) type package. The support member 110 may have the through-hole 110H. The semiconductor chip 120 may be disposed in the through-hole 110H to be spaced apart from the support member 110 by a predetermined distance. Side surfaces of the semiconductor chip 120 may be surrounded by the support member 110. However, such a form is only an example and may be variously modified to have other forms, and the support member 110 may perform another function depending on such a form. The support member 110 may be omitted, if necessary, but it may be more advantageous in securing board level reliability intended in the present disclosure that the fan-out semiconductor package 100A includes the support member 110.

The support member 110 may include an insulating layer 111. An insulating material may be used as a material of the insulating layer 111. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, Ajinomoto Build up Film (ABF), FR-4, Bismaleimide Triazine (BT), or the like.

The semiconductor chip 120 may be an integrated circuit (IC) provided in an amount of several hundreds to several millions of elements or more integrated in a single chip. In this case, the IC may be, for example, a processor chip (more specifically, an application processor (AP)) such as a central processor (for example, a CPU), a graphic processor (for example, a GPU), a field programmable gate array (FPGA), a digital signal processor, a cryptographic processor, a micro processor, a micro controller, or the like, but is not limited thereto. That is, the IC may be a logic chip such as an analog-to-digital converter, an application-specific IC (ASIC), or the like, or a memory chip such as a volatile memory (for example, a DRAM), a non-volatile memory (for example, a ROM), a flash memory, or the like. In addition, the abovementioned elements may also be combined with each other and be disposed.

The semiconductor chip 120 may be formed on the basis of an active wafer. In this case, a base material of a body 121 may be silicon (Si), germanium (Ge), gallium arsenide (GaAs), or the like. Various circuits may be formed on the body 121. The connection pads 122 may electrically connect the semiconductor chip 120 to other components. A material of each of the connection pads 122 may be a conductive material such as aluminum (Al), or the like. A passivation layer 123 exposing the connection pads 122 may be formed on the body 121, and may be an oxide film, a nitride film, or the like, or a double layer of an oxide layer and a nitride layer. A lower surface of the connection pad 122 may have a step with respect to a lower surface of the encapsulant 130 through the passivation layer 123. Resultantly, a phenomenon in which the encapsulant 130 bleeds into the lower surface of the connection pads 122 may be prevented to some extent. An insulating layer (not illustrated), and the like, may also be further disposed in other required positions. The semiconductor chip 120 may be a bare die, a redistribution layer (not illustrated) may be further formed on the active surface of the semiconductor chip 120, if necessary, and bumps (not illustrated), or the like, may be connected to the connection pads 122.

The encapsulant 130 may protect the support member 110, the semiconductor chip 120, and the like. An encapsulation form of the encapsulant 130 is not particularly limited, but may be a form in which the encapsulant 130 surrounds at least portions of the support member 110, the semiconductor chip 120, and the like. For example, the encapsulant 130 may cover the support member 110 and the inactive surface of the semiconductor chip 120, and fill spaces between walls of the through-hole 110H and the side surfaces of the semiconductor chip 120. In addition, the encapsulant 130 may also fill at least a portion of a space between the passivation layer 123 of the semiconductor chip 120 and the connection member 140. Meanwhile, the encapsulant 130 may fill the through-hole 110H to thus serve as an adhesive and reduce buckling of the semiconductor chip 120 depending on certain materials.

A material of the encapsulant 130 is not particularly limited. For example, an insulating material may be used as the material of the encapsulant 130. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, ABF, FR-4, BT, or the like. Alternatively, a PID resin may also be used as the insulating material.

The connection member 140 may be configured to redistribute the connection pads 122 of the semiconductor chip 120. Several ten to several hundred connection pads 122 having various functions may be redistributed by the connection member 140, and may be physically or electrically connected to an external source through connection terminals 170 to be described below depending on the functions. The connection member 140 may include insulating layers 141a and 141b, redistribution layers 142a and 142b disposed on the insulating layers 141a and 141b, respectively, and vias 143a and 143b penetrating through the insulating layers 141a and 141b, respectively, and connecting the redistribution layers 142a and 142b to each other. In the fan-out semiconductor package 100A according to the exemplary embodiment, the connection member 140 may include a plurality of redistribution layers 142a and 142b, but is not limited thereto. That is, the second connection member 140 may also include a single layer. In addition, the connection member 140 may also include different numbers of layers.

An insulating material may be used as a material of each of the insulating layers 141a and 141b. In this case, a photosensitive insulating material such as a photoimagable dielectric (PID) resin may also be used as the insulating material. In this case, each of the insulating layers 141a and 141b may be formed to have a smaller thickness, and a fine pitch of each of the vias 143a and 143b may be achieved more easily. Materials of the insulating layers 141a and 141b may be the same as each other or may be different from each other, if necessary. The insulating layers 141a and 141b may be integrated with each other depending on processes, so that a boundary therebetween may not be readily apparent.

The redistribution layers 142a and 142b may serve to substantially redistribute the connection pads 122. A material of each of the redistribution layers 142a and 142b may be a conductive material such as copper (Cu), aluminum (Al), silver (Ag), tin (Sn), gold (Au), nickel (Ni), lead (Pb), titanium (Ti), or alloys thereof. The redistribution layers 142a and 142b may perform various functions depending on designs of their corresponding layers. For example, the redistribution layers 142a and 142b may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the redistribution layers 142a and 142b may include via pads, connection terminal pads, and the like.

A surface treatment layer (not illustrated) may be further formed on portions of the redistribution layer 142b exposed from the redistribution layers 142a and 142b, if necessary. The surface treatment layer (not illustrated) is not particularly limited as long as it is known in the related art, but may be formed by, for example, electrolytic gold plating, electroless gold plating, organic solderability preservative (OSP) or electroless tin plating, electroless silver plating, electroless nickel plating/substituted gold plating, direct immersion gold (DIG) plating, hot air solder leveling (HASL), or the like.

The vias 143a and 143b may electrically connect the redistribution layers 142a and 142b, the connection pads 122, or the like, formed on different layers to each other, resulting in an electrical path in the fan-out semiconductor package 100A. A material of each of the vias 143a and 143b may be a conductive material such as copper (Cu), aluminum (Al), silver (Ag), tin (Sn), gold (Au), nickel (Ni), lead (Pb), titanium (Ti), or alloys thereof. Each of the vias 143a and 143b may be completely filled with the conductive material, or the conductive material may also be formed along a wall of each of the vias. In addition, each of the vias 143a and 143b may have all of the shapes known in the related art, such as a tapered shape, a cylindrical shape, and the like.

The passivation layer 150 may be additionally configured to protect the connection member 140 from external physical or chemical damage. The passivation layer 150 may have the openings 150H exposing at least portions of one 142b of the redistribution layers 142a and 142b of the connection member 140. The openings 150H may expose the entirety or only a portion of a surface of the redistribution layer 142b. A material of the passivation layer 150 is not particularly limited, but may be a photosensitive insulating material such as a PID resin. Alternatively, a solder resist may also be used as the material of the passivation layer 150. Alternatively, an insulating resin that does not include a core material, but includes a filler, for example, ABF including an inorganic filler and an epoxy resin may be used as the material of the passivation layer 150. When an insulating material that includes an inorganic filler and an insulating resin, but does not include a core material, for example, the ABF, or the like, is used as the material of the passivation layer 150, the passivation layer 150 and a resin layer 190 to be described below may have a symmetrical effect to each other, which may be more effective in controlling the warpage.

When the insulating material including the inorganic filler and the insulating resin, for example, the ABF, or the like, is used as the material of the passivation layer 150, the insulating layers 141a and 141b of the connection member 140 may also include an inorganic filler and an insulating resin. In this case, a weight percent of inorganic filler included in the passivation layer 150 may be greater than that of inorganic filler included in the insulating layers 141a and 141b of the connection member 140. In this case, the passivation layer 150 may have a relatively low CTE, and may be utilized to control the warpage, similar to the reinforcing plate 180.

The underbump metal layer 160 may be additionally configured to improve connection reliability of the connection terminals 170 to improve board level reliability of the fan-out semiconductor package 100A. The underbump metal layer 160 may be disposed on walls in the openings 150H of the passivation layer 150 and the exposed redistribution layer 142b of the connection member 140. The underbump metal layer 160 may be formed by the known metallization method using the known conductive material such as a metal.

The connection terminals 170 may be additionally configured to physically or electrically externally connect the fan-out semiconductor package 100A. For example, the fan-out semiconductor package 100A may be mounted on the main board of the electronic device through the connection terminals 170. Each of the connection terminals 170 may be formed of a conductive material, for example, a solder, or the like. However, this is only an example, and a material of each of the connection terminals 170 is not particularly limited thereto. Each of the connection terminals 170 may be a land, a ball, a pin, or the like. The connection terminals 170 may be formed as a multilayer or single layer structure. When the connection terminals 170 are formed as a multilayer structure, the connection terminals 170 may include a copper (Cu) pillar and a solder. When the connection terminals 170 are formed as a single layer structure, the connection terminals 170 may include a tin-silver solder or copper (Cu). However, this is only an example, and the connection terminals 170 are not limited thereto. The number, an interval, a disposition, or the like, of the connection terminals 170 is not particularly limited, but may be sufficiently modified by a person skilled in the art depending on design particulars. For example, the connection terminals 170 may be provided in an amount of several tens to several thousands according to the number of connection pads 122 of the semiconductor chip 120, but are not limited thereto, and may also be provided in an amount of several tens to several thousands or more or several tens to several thousands or less.

At least one of the connection terminals 170 may be disposed in a fan-out region. The fan-out region is a region except for a region in which the semiconductor chip 120 is disposed. That is, the fan-out semiconductor package 100A according to the exemplary embodiment may be a fan-out package. The fan-out package may have excellent reliability as compared to a fan-in package, may implement a plurality of input/output (I/O) terminals, and may facilitate a 3D interconnection. In addition, as compared to a ball grid array (BGA) package, a land grid array (LGA) package, or the like, the fan-out package may be mounted on an electronic device without a separate board. Thus, the fan-out package may be manufactured to have a small thickness, and may have price competitiveness.

The reinforcing plate 180 may suppress a warpage generated in the fan-out semiconductor package 100A. For example, the reinforcing plate 180 may suppress the hardening contraction of materials of the encapsulant 130 and the resin layer 190, such as a thermosetting resin film to suppress the warpage of the fan-out semiconductor package 100A. The reinforcing plate 180 may have an elastic modulus relatively greater than that of the encapsulant 130, and may have a CTE smaller than that of the encapsulant 130. In this case, a warpage suppressing effect may be more excellent.

The reinforcing plate 180 may include a core material, an inorganic filler, and an insulating resin. For example, the reinforcing plate 180 may be formed of an unclad copper clad laminate (CCL), prepreg, or the like. As described above, when the reinforcing plate 180 includes the core material such as a glass cloth (or a glass fabric), the reinforcing plate 180 may be implemented to have a relatively large elastic modulus, and when the reinforcing plate 180 includes the inorganic filler, a CTE of the reinforce plate 180 may be adjusted by adjusting a content of the inorganic filler. The reinforcing plate 180 may be attached in a hardened state (a c-stage) to the encapsulant 130. In this case, a boundary surface between the encapsulant 130 and the reinforcing plate 180 may have an approximately linear shape. The inorganic filler may be silica, alumina, or the like, and the resin may be an epoxy resin, or the like. However, the inorganic filler and the resin are not limited thereto.

The reinforcing plate 180 may have a first surface facing the inactive surface of the semiconductor chip 120 and a second surface opposing the first surface, and the rigid patterns 182 may be formed on the first surface of the reinforcing plate 180 as an example. The rigid patterns 182 may make the reinforcing plate 180 more rigid to allow the warpage to be more effectively controlled. In addition, the rigid patterns 182 may be embedded in the encapsulant 130 and prevent the flow of the encapsulant 130 to reduce the non-uniformity of the thickness of the encapsulant 130 and prevent the void defect or the bleeding defect of the encapsulant 130. The CTE may also be adjusted through the rigid patterns 182. The rigid patterns 182 may include a metal such as copper (Cu), or the like, and may also include an organic material that may have a rigid property. The rigid patterns 182 may include a plurality of patterns spaced apart from each other, and sizes of the respective patterns may be the same as or different from each other.

The resin layer 190 may be disposed on the reinforcing plate 180. The resin layer 190 may be formed of a material that is the same as or similar to that of the encapsulant 130 and/or the passivation layer 150, for example, an insulating material that includes an inorganic filler and an insulating resin, but does not include a core material, that is, ABF, or the like. When the reinforcing plate 180 includes the core material, or the like, it is difficult to form openings in the reinforcing plate 180 itself, but when the resin layer 190 is added, the openings may be easily formed. When the resin layer 190 is disposed, the warpage may be more easily suppressed.

If necessary, a plurality of semiconductor chips (not illustrated) may be disposed in the through-hole 110H of the support member 110, and the number of through-holes 110H of the support member 110 may be plural (not illustrated) and semiconductor chips (not illustrated) may be disposed in the through-holes, respectively. In addition, separate passive components (not illustrated) such as a condenser, an inductor, and the like, may be encapsulated together with the semiconductor chip in the through-hole 110H. In addition, a surface mounted technology component (not illustrated) may be mounted on the passivation layer 150.

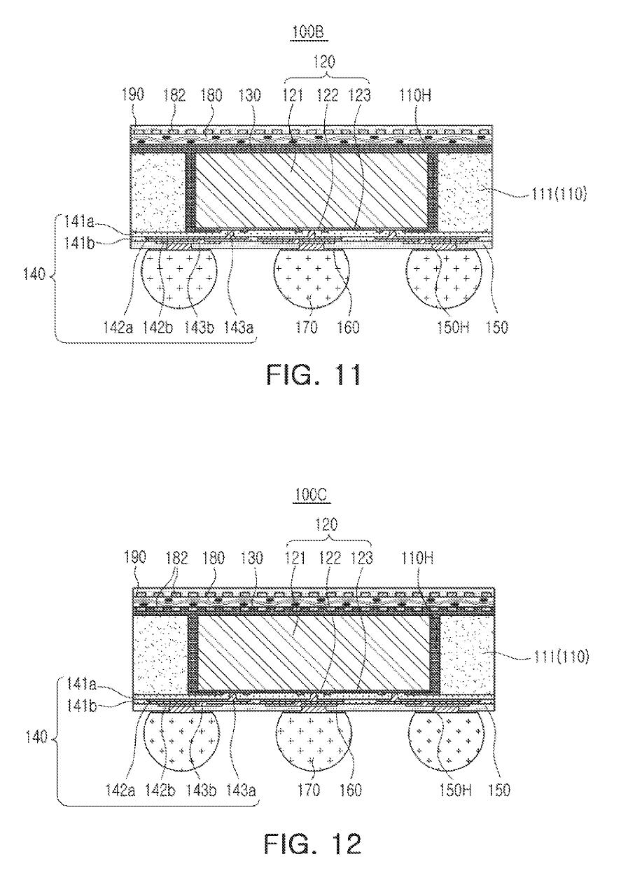

FIG. 11 is a schematic cross-sectional view illustrating another example of a fan-out semiconductor package.

Referring to the drawing, in a fan-out semiconductor package 100B according to another exemplary embodiment in the present disclosure, rigid patterns 182 may be formed on a second surface, that is, an upper surface, of a reinforcing plate 180. In this case, the rigid patterns 182 may control stress due to hardening contraction of the resin layer 190. Also in a case in which the rigid patterns 182 are formed on the second surface of the reinforcing plate 180, the rigid patterns 182 may further provide a rigid property to the reinforcing plate 180 to effectively control a warpage. Other contents overlap those described above, and a detailed description thereof is thus omitted.

FIG. 12 is a schematic cross-sectional view illustrating another example of a fan-out semiconductor package.

Referring to the drawing, in a fan-out semiconductor package 100C according to another exemplary embodiment in the present disclosure, rigid patterns 182 may be formed on both of a first surface and a second surface of a reinforcing plate 180. In this case, the rigid patterns 182 may control stress due to hardening contraction of both of the encapsulant 130 and the resin layer 190. In addition, the rigid patterns 182 may further provide a rigid property to the reinforcing plate 180 to more effectively control a warpage. Other contents overlap those described above, and a detailed description thereof is thus omitted.

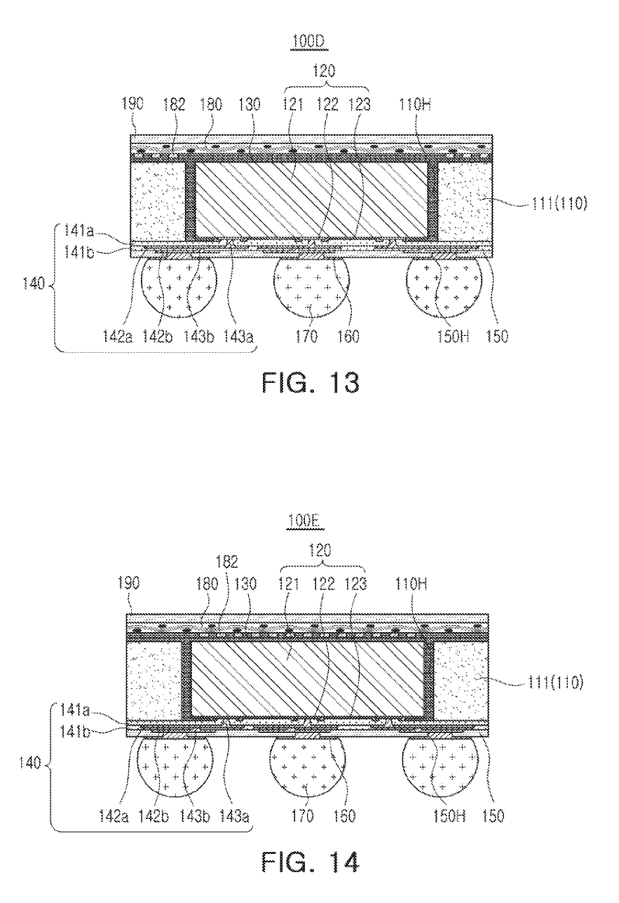

FIG. 13 is a schematic cross-sectional view illustrating another example of a fan-out semiconductor package.

Referring to the drawing, in a fan-out semiconductor package 100D according to another exemplary embodiment in the present disclosure, rigid patterns 182 may be formed in only a fan-out region on a first surface of a reinforcing plate 180. That is, the rigid patterns 182 may also be formed in only the fan-out region in order to control unit warpages. Other contents overlap those described above, and a detailed description thereof is thus omitted.

FIG. 14 is a schematic cross-sectional view illustrating another example of a fan-out semiconductor package.

Referring to the drawing, in a fan-out semiconductor package 100E according to another exemplary embodiment in the present disclosure, rigid patterns 182 may be formed in only a fan-in region on a first surface of a reinforcing plate 180. That is, the rigid patterns 182 may also be formed in only the fan-in region in order to control unit warpages. Other contents overlap those described above, and a detailed description thereof is thus omitted.

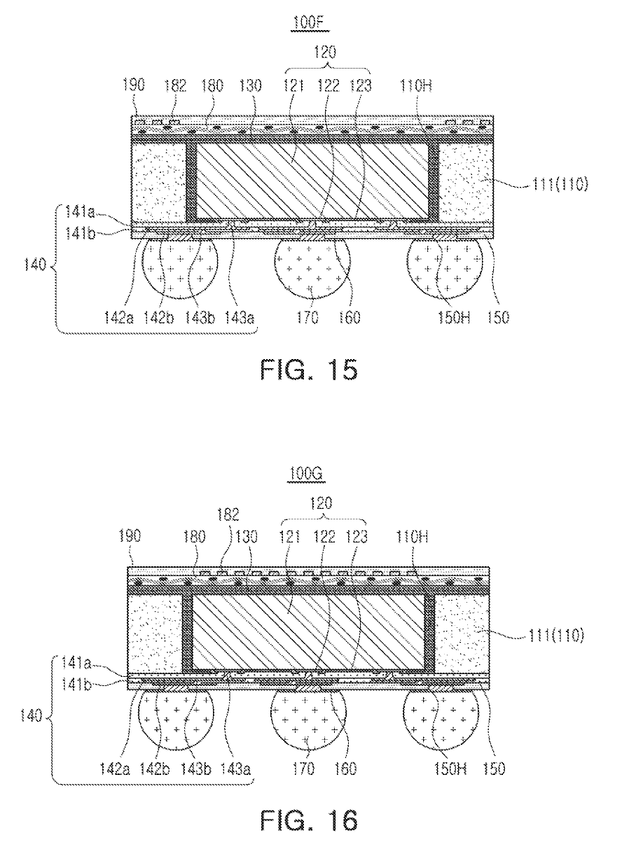

FIG. 15 is a schematic cross-sectional view illustrating another example of a fan-out semiconductor package.

Referring to the drawing, in a fan-out semiconductor package 100F according to another exemplary embodiment in the present disclosure, rigid patterns 182 may be formed in only a fan-out region on a second surface of a reinforcing plate 180. That is, the rigid patterns 182 may also be formed in only the fan-out region in order to control unit warpages. Other contents overlap those described above, and a detailed description thereof is thus omitted.

FIG. 16 is a schematic cross-sectional view illustrating another example of a fan-out semiconductor package.

Referring to the drawing, in a fan-out semiconductor package 100G according to another exemplary embodiment in the present disclosure, rigid patterns 182 may be formed in only a fan-in region on a second surface of a reinforcing plate 180. That is, the rigid patterns 182 may also be formed in only the fan-in region in order to control unit warpages. Other contents overlap those described above, and a detailed description thereof is thus omitted.

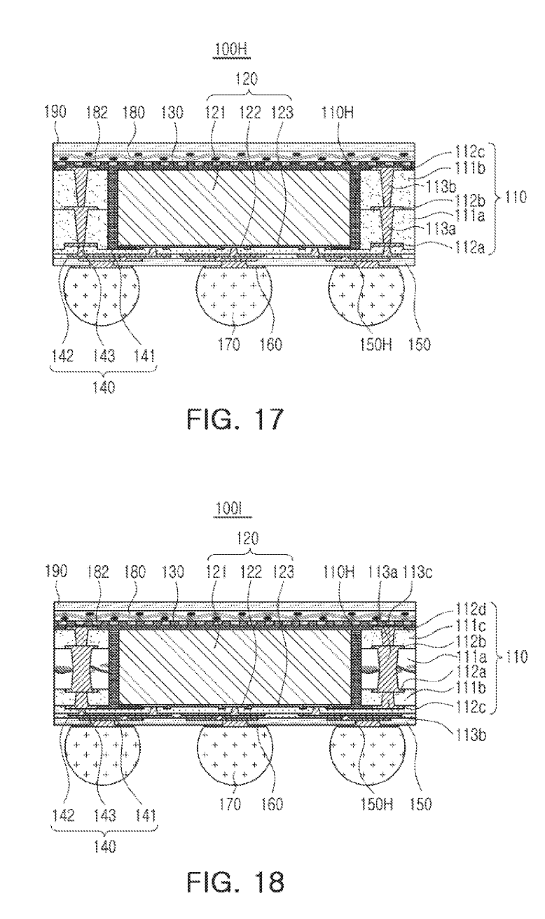

FIG. 17 is a schematic cross-sectional view illustrating another example of a fan-out semiconductor package.

Referring to the drawing, in a fan-out semiconductor package 100H according to another exemplary embodiment in the present disclosure, a support member 110 may include a first insulating layer 111a in contact with a connection member 140, a first redistribution layer 112a in contact with the connection member 140 and embedded in a first surface of the first insulating layer 111a, a second redistribution layer 112b disposed on a second surface of the first insulating layer 111a opposing the first surface of the first insulating layer 111a, a second insulating layer 111b disposed on the first insulating layer 111a and covering the second redistribution layer 112b, and a third redistribution layer 112c disposed on the second insulating layer 111b. The first to third redistribution layers 112a, 112b, and 112c may be electrically connected to connection pads 122. The first and second redistribution layers 112a and 112b and the second and third redistribution layers 112b and 112c may be electrically connected to each other through first and second vias 113a and 113b penetrating through the first and second insulating layers 111a and 111b, respectively.

When the first redistribution layer 112a is embedded in the first insulating layer 111a, a step generated due to a thickness of the first redistribution layer 112a may be significantly reduced, and an insulating distance of the connection member 140 may thus become constant. That is, a difference between a distance from a first redistribution layer 142a of the connection member 140 to a lower surface of the first insulating layer 111a and a distance from the first redistribution layer 142a of the connection member 140 to the connection pad 122 of a semiconductor chip 120 may be smaller than a thickness of the first redistribution layer 112a. Therefore, a high density wiring design of the connection member 140 may be easy.

A lower surface of the first redistribution layer 112a of the support member 110 may be disposed on a level above a lower surface of the connection pad 122 of the semiconductor chip 120. In addition, a distance between the first redistribution layer 142a of the connection member 140 and the first redistribution layer 112a of the support member 110 may be greater than that between the first redistribution layer 142a of the connection member 140 and the connection pad 122 of the semiconductor chip 120. Here, the first redistribution layer 112a may be recessed into the first insulating layer 111a. As described above, when the first redistribution layer 112a is recessed into the first insulating layer 111a, such that the lower surface of the first insulating layer 111a and the lower surface of the first redistribution layer 112a have a step therebetween, a phenomenon in which a material of the encapsulant 130 bleeds to pollute the first redistribution layer 112a may be prevented. The second redistribution layer 112b of the support member 110 may be disposed on a level between an active surface and an inactive surface of the semiconductor chip 120. The support member 110 may be formed at a thickness corresponding to that of the semiconductor chip 120. Therefore, the second redistribution layer 112b formed in the support member 110 may be disposed on the level between the active surface and the inactive surface of the semiconductor chip 120.

Thicknesses of the redistribution layers 112a, 112b, and 112c of the support member 110 may be greater than those of the redistribution layers 142a and 142b of the connection member 140. Since the support member 110 may have a thickness equal to or greater than that of the semiconductor chip 120, the redistribution layers 112a, 112b, and 112c may be formed at large sizes depending on a scale of the support member 110. On the other hand, the redistribution layers 142a and 142b of the connection member 140 may be formed at sizes relatively smaller than those of the redistribution layers 112a, 112b, and 112c for thinness.

A material of each of the insulating layers 111a and 111b is not particularly limited. For example, an insulating material may be used as the material of each of the insulating layers 111a and 111b. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, ABF, FR-4, BT, or the like. Alternatively, a PID resin may also be used as the insulating material.

The redistribution layers 112a, 112b, and 112c may serve to redistribute the connection pads 122 of the semiconductor chip 120. A material of each of the redistribution layers 112a, 112b, and 112c may be a conductive material such as copper (Cu), aluminum (Al), silver (Ag), tin (Sn), gold (Au), nickel (Ni), lead (Pb), titanium (Ti), or alloys thereof. The redistribution layers 112a, 112b, and 112c may perform various functions depending on designs of their corresponding layers. For example, the redistribution layers 112a, 112b, and 112c may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the redistribution layers 112a, 112b, and 112c may include via pads, wire pads, connection terminal pads, and the like.

The vias 113a and 113b may electrically connect the redistribution layers 112a, 112b, and 112c formed on different layers to each other, resulting in an electrical path in the support member 110. A material of each of the vias 113a and 113b may be a conductive material. Each of the vias 113a and 113b may be completely filled with the conductive material, or the conductive material may also be formed along a wall of each of via holes. In addition, each of the vias 113a and 113b may have all of the shapes known in the related art, such as a tapered shape, a cylindrical shape, and the like. When holes for the first vias 113a are formed, some of the pads of the first redistribution layer 112a may serve as a stopper, and it may thus be advantageous in a process that each of the first vias 113a has the tapered shape of which a width of an upper surface is greater than that of a lower surface. In this case, the first vias 113a may be integrated with the pad patterns of the second redistribution layer 112b. In addition, when holes for the second vias 113b are formed, some of the pads of the second redistribution layer 112b may serve as a stopper, and it may thus be advantageous in a process that each of the second vias 113b has the tapered shape of which a width of an upper surface is greater than that of a lower surface. In this case, the second vias 113b may be integrated with the pad patterns of the third redistribution layer 112c.

Meanwhile, dispositions of the rigid patterns 182 of the fan-out semiconductor packages 100B to 100G according to another exemplary embodiment described above may also be applied to the fan-out semiconductor package 100H according to another exemplary embodiment, and other contents overlap those described above, and a detailed description thereof is thus omitted.

FIG. 18 is a schematic cross-sectional view illustrating another example of a fan-out semiconductor package.

Referring to the drawing, in a fan-out semiconductor package 100I according to another exemplary embodiment in the present disclosure, a support member 110 may include a first insulating layer 111a, a first redistribution layer 112a and a second redistribution layer 112b disposed on opposite surfaces of the first insulating layer 111a, respectively, a second insulating layer 111b disposed on the first insulating layer 111a and covering the first redistribution layer 112a, a third redistribution layer 112c disposed on the second insulating layer 111b, a third insulating layer 111c disposed on the first insulating layer 111a and covering the second redistribution layer 112b, and a fourth redistribution layer 112d disposed on the third insulating layer 111c. The first to fourth redistribution layers 112a, 112b, 112c, and 112d may be electrically connected to connection pads 122. Since the support member 110 may include a large number of redistribution layers 112a, 112b, 112c, and 112d, a connection member 140 may be further simplified. Therefore, a decrease in a yield depending on a defect occurring in a process of forming the connection member 140 may be suppressed. Meanwhile, the first to fourth redistribution layers 112a, 112b, 112c, and 112d may be electrically connected to each other through first to third vias 113a, 113b, and 113c each penetrating through the first to third insulating layers 111a, 111b, and 111c.

The first insulating layer 111a may have a thickness greater than those of the second insulating layer 111b and the third insulating layer 111c. The first insulating layer 111a may be basically relatively thick in order to maintain rigidity, and the second insulating layer 111b and the third insulating layer 111c may be introduced in order to form a larger number of redistribution layers 112c and 112d. The first insulating layer 111a may include an insulating material different from those of the second insulating layer 111b and the third insulating layer 111c. For example, the first insulating layer 111a may be, for example, prepreg including a core material, a filler, and an insulating resin, and the second insulating layer 111b and the third insulating layer 111c may be an ABF or a PID film including a filler and an insulating resin. However, the materials of the first insulating layer 111a and the second and third insulating layers 111b and 111c are not limited thereto. Similarly, the first vias 113a penetrating through the first insulating layer 111a may have a diameter greater than those of second vias 113b and third vias 113c each penetrating through the second insulating layer 111b and the third insulating layer 111c.

A lower surface of the third redistribution layer 112c of the support member 110 may be disposed on a level below a lower surface of the connection pad 122 of a semiconductor chip 120. In addition, a distance between a first redistribution layer 142a of the connection member 140 and the third redistribution layer 112c of the support member 110 may be smaller than that between the first redistribution layer 142a of the connection member 140 and the connection pad 122 of the semiconductor chip 120. Here, the third redistribution layer 112c may be disposed in a protruding form on the second insulating layer 111b, resulting in being in contact with the connection member 140. The first redistribution layer 112a and the second redistribution layer 112b of the support member 110 may be disposed on a level between an active surface and an inactive surface of the semiconductor chip 120. The support member 110 may be formed at a thickness corresponding to that of the semiconductor chip 120. Therefore, the first redistribution layer 112a and the second redistribution layer 112b formed in the support member 110 may be disposed on the level between the active surface and the inactive surface of the semiconductor chip 120.

Thicknesses of the redistribution layers 112a, 112b, 112c, and 112d of the support member 110 may be greater than those of the redistribution layers 142a and 142b of the connection member 140. Since the support member 110 may have a thickness equal to or greater than that of the semiconductor chip 120, the redistribution layers 112a, 112b, 112c, and 112d may be formed at large sizes. On the other hand, the redistribution layers 142a and 142b of the connection member 140 may be formed at relatively small sizes for thinness.

Meanwhile, dispositions of the rigid patterns 182 of the fan-out semiconductor packages 100B to 100G according to another exemplary embodiment described above may also be applied to the fan-out semiconductor package 100I according to another exemplary embodiment, and other contents overlap those described above, and a detailed description thereof is thus omitted.

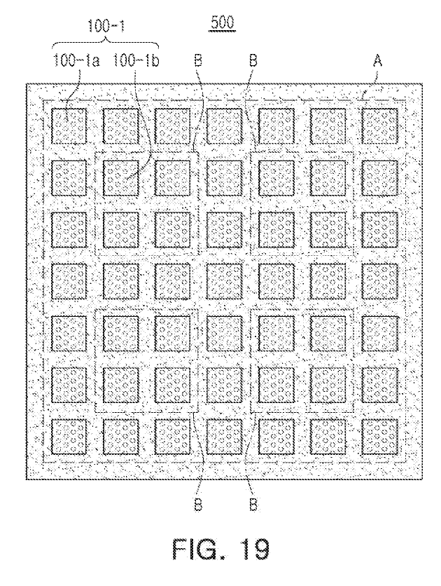

FIG. 19 is a schematic plan view illustrating an example of a package substrate including a plurality of fan-out semiconductor packages.

Referring to the drawing, a plurality of fan-out semiconductor packages 100-1 according to the various exemplary embodiments described above may be formed through a package substrate 500, and individual fan-out semiconductor packages 100-1 may be obtained through a cutting process, or the like. Meanwhile, unit warpages of a plurality of unit packages 100-1 in the package substrate 500 may be relatively different from each other. In this case, the unit warpages may be controlled by making ratios of rigid patterns 182 relatively different from each other. That is, the warpages may be controlled by forming a larger number of rigid patterns 182 in unit packages 100-1a of which unit warpage is relatively high and forming a smaller number of rigid patterns 182 in unit packages 100-1b of which unit warpage is relatively low. For example, the unit warpages may be intensified toward an edge A of the package substrate 500. Therefore, in a case of unit packages 100-1 formed at the edge A of the package substrate 500, rigid patterns 182 may be formed in a high ratio on reinforcing plates 180. In more detail, the unit packages 100-1a formed at the edge A of the package substrate 500 may include a larger number of rigid patterns 182 as compared to the unit packages 100-1b formed at inner sides B of the edge A. However, all the cases are not limited thereto, and the ratios of rigid patterns 182 may be relatively controlled depending on the unit warpages.

As set forth above, according to the exemplary embodiment in the present disclosure, a fan-out semiconductor package in which a warpage problem may be effectively solved, and a package substrate including the same may be provided.

While exemplary embodiments have been shown and described above, it will be apparent to those skilled in the art that modifications and variations could be made without departing from the scope of the present invention as defined by the appended claims.

What is claimed is:

1. A fan-out semiconductor package comprising:
a semiconductor chip having an active surface having connection pads disposed thereon and an inactive surface opposing the active surface;
an encapsulant encapsulating at least portions of the inactive surface of the semiconductor chip;
a connection member disposed on the active surface of the semiconductor chip and including a redistribution layer electrically connected to the connection pads of the semiconductor chip;
a reinforcing plate disposed on the encapsulant and having a first surface facing the inactive surface of the semiconductor chip and a second surface opposing the first surface; and
rigid patterns disposed on at least one of the first surface and the second surface of the reinforcing plate.

2. The fan-out semiconductor package of claim 1, wherein the reinforcing plate has an elastic modulus greater than that of the encapsulant.

3. The fan-out semiconductor package of claim 1, wherein the reinforcing plate includes a glass fiber, an inorganic filler, and an insulating resin.

4. The fan-out semiconductor package of claim 3, further comprising a resin layer disposed on the second surface of the reinforcing plate,
wherein the resin layer includes an inorganic filler and an insulating resin.

5. The fan-out semiconductor package of claim 1, wherein the rigid patterns include a metal or an organic material.

6. The fan-out semiconductor package of claim 1, wherein the rigid patterns are formed in only a fan-in region or a fan-out region.

7. The fan-out semiconductor package of claim 1, wherein the rigid patterns are formed on the first surface of the reinforcing plate, and are embedded in the encapsulant.

8. The fan-out semiconductor package of claim 1, further comprising a resin layer disposed on the second surface of the reinforcing plate,
wherein the rigid patterns are formed on the second surface of the reinforcing plate, and are embedded in the resin layer.

9. The fan-out semiconductor package of claim 1, further comprising a support member having a through-hole,
wherein the semiconductor chip is disposed in the through-hole.

10. The fan-out semiconductor package of claim 9, wherein the support member includes a first insulating layer, a first redistribution layer in contact with the connection member and embedded in a first surface of the first insulating layer, and a second redistribution layer disposed on a second surface of the first insulating layer opposing the first surface of the first insulating layer, and
the first and second redistribution layers are electrically connected to the connection pads.

11. The fan-out semiconductor package of claim 10, wherein the support member further includes a second insulating layer disposed on the first insulating layer and covering the second redistribution layer and a third redistribution layer disposed on the second insulating layer, and
the third redistribution layer is electrically connected to the connection pads.

12. The fan-out semiconductor package of claim 10, wherein a distance between the redistribution layer of the connection member and the first redistribution layer is greater than that between the redistribution layer of the connection member and the connection pad.

13. The fan-out semiconductor package of claim 9, wherein the support member includes a first insulating layer, a first redistribution layer and a second redistribution layer disposed on opposite surfaces of the first insulating layer, respectively, a second insulating layer disposed on the first insulating layer and covering the first redistribution layer, and a third redistribution layer disposed on the second insulating layer, and
the first to third redistribution layers are electrically connected to the connection pads.

14. The fan-out semiconductor package of claim 13, wherein the support member further includes a third insulating layer disposed on the first insulating layer and covering the second redistribution layer and a fourth redistribution layer disposed on the third insulating layer, and
the fourth redistribution layer is electrically connected to the connection pads.

15. The fan-out semiconductor package of claim 13, wherein the first insulating layer has a thickness greater than that of the second insulating layer.

16. A fan-out semiconductor package comprising:
a semiconductor chip having an active surface having connection pads disposed thereon and an inactive surface opposing the active surface;
an encapsulant encapsulating at least portions of the inactive surface of the semiconductor chip;
a connection member disposed on the active surface of the semiconductor chip and including a redistribution layer electrically connected to the connection pads of the semiconductor chip; and
a reinforcing plate disposed on the encapsulant and having a first surface facing the inactive surface of the semiconductor chip and a second surface opposing the first surface,
wherein the reinforcing plate has a coefficient of thermal expansion smaller than that of the encapsulant.

17. The fan-out semiconductor package of claim 16, further comprising rigid patterns disposed on at least one of the first surface and the second surface of the reinforcing plate.

18. The fan-out semiconductor package of claim 16, wherein the reinforcing plate has an elastic modulus greater than that of the encapsulant.

19. A package substrate comprising:
a plurality of unit packages each including a semiconductor chip having an active surface having connection pads disposed thereon and an inactive surface opposing the active surface, an encapsulant encapsulating at least portions of the inactive surface of the semiconductor chip, a connection member disposed on the active surface of the semiconductor chip and including a redistribution layer electrically connected to the connection pads of the semiconductor chip, a reinforcing plate disposed on the encapsulant and having a first surface facing the inactive surface of the semiconductor chip and a second surface opposing the first surface, and rigid patterns formed on at least one of the first surface and the second surface of the reinforcing plate.

20. The package substrate of claim 19, wherein a larger number of rigid patterns are formed in unit packages, among the plurality of unit packages, in which unit warpage is relatively high, than in unit packages, among the plurality of unit packages, in which unit warpage is relatively low.
